(19) United States
(12) Patent Application Publication
(10) Pub. No.: US 2025/0232947 A1
(43) Pub. Date: Jul. 17, 2025

(54) Charged Particle Beam System

(71) Applicant: Hitachi High-Tech Corporation, Minato-ku, Tokyo (JP)

(72) Inventors: Naoto ITO, Tokyo (JP); Yu YAMAZAWA, Tokyo (JP); Tsunenori NOMAGUCHI, Tokyo (JP)

(21) Appl. No.: 18/853,446

(22) PCT Filed: Apr. 15, 2022
(86) PCT No.: PCT/JP2022/017912

§ 371 Date: Oct. 2, 2024

(51) Int. Cl. H01J 37/26; H01J 37/147; H01J 37/28

(52) U.S. Cl. CPC H01J 37/265; H01J 37/1474; H01J 37/28; H01J 2237/1534

(57) ABSTRACT

The present disclosure provides a charged particle beam system capable of appropriately setting an image generation condition for evaluating an adjustment condition for a beam. The charged particle beam system includes a scanning deflector and an adjustment deflector configured to adjust a trajectory of a beam to be incident on an optical element. In the system, a user interface configured to display an image and a partial region of the image selected by a user is provided, and an input portion (170) for allowing the user to set at least one of the image (initial screen 151), the partial region (152), a first parameter relating to a scanning speed of the scanning deflector, and a second parameter relating to a change speed of the optical element is displayed on the user interface (see FIG. 6).

### TECHNICAL FIELD

The present disclosure relates to a charged particle beam system, and for example, relates to a charged particle beam system including an adjustment element used to appropriately pass a beam through an optical element such as a lens or an astigmatic corrector.

### BACKGROUND ART

A charged particle beam system such as a scanning electron microscope (SEM) or a focused ion beam (FIB) device is used for observation and analysis of a microstructure using an image generated based on detection of secondary electrons or the like generated by irradiation with a charged particle beam and is used for processing using a sputtering phenomenon occurring when a sample is irradiated with a charged particle beam. The charged particle beam system is widely used mainly in the fields of semiconductor, materials, and biotechnology. In these fields, a further improvement in image resolution and a further improvement in analysis and processing accuracy are required accompanying the miniaturization of an observation sample.

To achieve the improvements, it is important to narrow down a charged particle beam diameter. In order to narrow down the beam diameter, there is an important operation of adjusting a beam irradiation axis (hereinafter referred to as optical axis adjustment) so as to reduce a lens aberration. In other words, it is an important operation of aligning an ideal optical axis of an optical element such as an electromagnetic lens with a beam trajectory.

In this regard, for example, PTL 1 discloses (wobbler adjustment method) performing axis adjustment based on an image shift amount caused by a wobbler.

### CITATION LIST

### Patent Literature

PTL 1: JP2016-143558A

### SUMMARY OF INVENTION

### Technical Problem

In the wobbler adjustment method disclosed in PTL 1, an adjustment condition provided by an adjustment element such as an axis adjustment deflector is derived based on movement amounts and movement directions of an object in an image before and after a change of an optical element. When evaluating the movement amount and the movement direction, it is desirable to use an image generated under appropriate conditions.

In view of such a situation, the present disclosure proposes a technique of appropriately setting an image generation condition for evaluating an adjustment condition for a charged particle beam.

### Solution to Problem

As an aspect for achieving the above object, the present disclosure proposes a charged particle beam system including: a charged particle beam column including a scanning deflector configured to perform scanning with a beam emitted from a charged particle source, an optical element configured to adjust the beam, and an adjustment deflector configured to adjust a trajectory of the beam incident on the optical element; and one or more computer subsystems connected to the charged particle beam column and configured to control the scanning deflector and the adjustment deflector. The one or more computer subsystems include a user interface configured to display an image output from the charged particle beam column and a partial region of the image selected by a user. The one or more computer subsystems periodically change an optical condition of the optical element, generate an image based on a signal output from the charged particle beam column when the optical condition of the optical element is periodically changed, and display, on the user interface, an input portion for allowing a user to set at least one of the generated image, the partial region, a first parameter relating to a scanning speed of the scanning deflector, or a second parameter relating to a change speed of the optical element.

Additional features related to the present disclosure will be clarified based on the description of the present description and the accompanying drawings. Aspects of the present disclosure may be achieved and implemented using elements, combinations of various elements, the following detailed description, and accompanying claims.

It is necessary to understand that description of the present description is merely a typical example, and is not intended to limit the scope of the claims or application examples of the present disclosure in any way.

### Advantageous Effects of Invention

According to the above configuration, it is possible to appropriately set an image generation condition for evaluating an adjustment condition for a beam.

### BRIEF DESCRIPTION OF DRAWINGS

FIG. 1 is a schematic diagram of an image obtained by superimposing and displaying a third image (an image acquired in a wobbler setting region) on a first image (a low-magnification image).

FIG. 2 is a diagram illustrating a schematic configuration example of a charged particle beam system (SEM system 100) according to an embodiment.

FIG. 3 is a diagram illustrating an example in which a frame (region 152: a partial region) indicating a wobbler selection region is superimposed and displayed on an initial screen 151 (a first image).

FIG. 4 is a diagram illustrating an example of a state in which an image region in which an in-focus image region and an out-of-focus region, in which an image is blurred, periodically appear in a wobbler adjustment image (region 152).

FIG. 5 is a flowchart illustrating setting processing of a wobbler condition in an SEM system (charged particle beam system) 100 including a user interface as illustrated in FIG. 3.

FIG. 6 is a diagram illustrating an example 1 of a GUI screen for setting a wobbler condition.

FIG. 7 is a diagram illustrating an example 2 of a GUI screen for setting a wobbler condition.

FIG. 8 is a flowchart for illustrating setting processing in which the user interface in FIG. 6 or 7 is used.

FIG. 9 is a flowchart illustrating processing of performing optical axis adjustment by using the SEM system (charged particle beam system) 100 including the user interface.

FIG. 10 is a diagram illustrating a configuration example of a user interface according to Embodiment 3.

FIG. 11 is a flowchart illustrating an example of optical axis adjustment processing in which the user interface illustrated in FIG. 10 is used.

FIG. 12 is a diagram illustrating a configuration example of a user interface according to Embodiment 4.

FIG. 13 is a flowchart illustrating optical axis adjustment processing in which the user interface illustrated in FIG. 12 is used.

FIG. 14 is a diagram illustrating a configuration example of a wobbler condition setting screen (GUI).

### DESCRIPTION OF EMBODIMENTS

### (1) Embodiments

### <Wobbling and Improvement of Wobbling>

Optical axis adjustment in a charged particle beam system is to pass a beam (a charged particle beam) through an ideal optical axis of an optical element such as a lens. At this time, a method of periodically changing an excitation current (lens strength) of a lens to be adjusted is called wobbling.

When the lens strength is periodically changed in a state where the beam is deviated from the ideal optical axis, the beam is deflected by a lens action, and an object in the field of view appears to be moving. On the other hand, when the beam passes through the lens along the ideal optical axis, even if the lens strength is changed, a focusing condition of the beam changes. The object does not move although the focusing condition changes. That is, an adjustment element (an alignment deflector or the like) performs adjustment such that the object in the field of view does not move even if wobbling is performed, whereby a beam trajectory and the ideal optical axis can be aligned with each other. In the following description, such an optical axis adjustment method is referred to as wobbler adjustment.

An ideal beam irradiation axis of the lens varies depending on a surface height position of a sample where the beam is focused. Therefore, it is desirable that strict optical axis adjustment for implementing image observation with a reduced aberration is performed at a surface height equal to the surface height of the sample to be observed.

An observation sample of the charged particle beam system includes a sample whose surface height is not uniform. That is, in a case where a region for acquiring a final image and a region for performing the wobbler adjustment are set at different positions in order to avoid overlapping irradiation on an observation region, there is a possibility that the height of the sample surface changes (differs) at an observation position and a position (wobbler adjustment region) away from the observation position, and thus it is desirable to set the wobbler adjustment region at a position in the vicinity of the observation position that is relatively close in height condition.

A sample placed on a mesh or a lamella may be an object to be processed and observed with the FIB. At this time, the surface of the sample placed on the mesh or lamella may be inclined with respect to the optical axis. Therefore, since the sample height changes (differs) at the observation position and a position away from the observation position, it is desirable to perform the wobbler adjustment in the vicinity of the observation position.

Further, there is a sample having a characteristic of being susceptible to charged particle beam irradiation, such as a resist pattern of a semiconductor device. When such a sample is to be observed, it is desirable to reduce the charged particle beam irradiation amount.

In view of such circumstances, it can be said that a region, which is at a position different from the observation region and is close to the observation region, is a region suitable for the wobbler adjustment region.

In order to set both the observation region and the wobbler setting region to appropriate regions as described above, first, it is desirable to acquire a low-magnification image (a wide field of view (FOV) image: a first image) so as to include the observation region, grasp the position of the observation region in the first image, and set a region located close to the observation region (an acquisition region for a second image) and having a small height difference from the observation region as the wobbler setting region (an acquisition region for a third image). However, a case where a steep inclination is present in the vicinity of the observation region or the observation region is surrounded by a member that is easily charged is not limited thereto.

On the other hand, a scanning time can be changed in the SEM or the like. Specifically, the scanning time can be adjusted by adjusting a scanning signal supplied from a power supply or the like connected to a scanning deflector. The scanning time can be adjusted, for example, in units of frames (one unit of two-dimensional scanning). By this adjustment, it is possible to select high-speed scanning for the purpose of reducing the beam irradiation amount (dose amount) or low-speed scanning for the purpose of improving the dose amount for securing sufficient signals (the amount of secondary electrons).

As described above, it is desirable to set the scanning time and the wobbler setting region according to the observation purpose and the sample condition, but it has become clear from the study of the inventors that an unnecessary striped pattern appears in an image of the wobbler setting region depending on a setting condition.

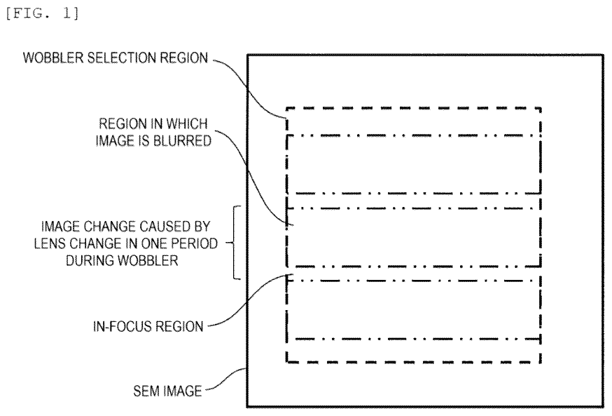

FIG. 1 is a schematic diagram of an image obtained by superimposing and displaying a third image (an image acquired in a wobbler setting region) on a first image (a low-magnification image). More specifically, an example is illustrated in which a real-time image for evaluating image shift due to wobbling is superimposed and displayed on a low-magnification image acquired in advance. By performing such superimposed display, it is possible to evaluate whether the conditions for acquiring the third image, such as the scanning time (frame time) and a wobbler time (for example, a time corresponding to one period of the excitation current in the case of an electromagnetic lens), are appropriate.

When generating the third image, if an irradiation time per pixel (a dwell time to be described later) is set to be longer than that for the first image, it is possible to increase the contrast in the wobbler setting region compared to that of the first image, and it is possible to increase the visibility of image shake. On the other hand, if the irradiation time (dwell time) for the third image is made coincident with that for the first image, the generation conditions of the first image and the third image can be made coincident. Therefore, the presence of the striped pattern appearing in the third image can be determined by relative comparison with the first image. By storing such conditions in a storage medium in advance and providing options such as a high contrast mode (in which the dwell time is longer than in other modes) or a low dose mode (in which the dwell time is shorter than in other modes) on a user interface, it is possible to select an appropriate generation condition of an image for wobbling according to a sample condition, an operator's preference, or the like.

When the operator sets a wobbler scanning region (a dotted frame in FIG. 1: an acquisition region of the third image), scanning with a beam is performed in the region. When wobbling is performed in this state, periodic image movement occurs due to a wobbler of the lens (a periodic change in excitation of the lens).

Here, when the frame time (a scanning time per frame for a wobbler selection region) is set to be delayed with respect to the wobbler time (a time corresponding to one period of the lens excitation change), a plurality of times of image movement occur in one frame, and this phenomenon is expressed as a striped pattern in the image as illustrated in FIG. 1. When the striped pattern coexists with the image shake caused by wobbling, it is not possible to appropriately evaluate the image shake, and as a result, it may be difficult to perform alignment (optical axis adjustment) with high accuracy. Therefore, it is desirable to perform wobbling with an appropriate setting, but it is considered that it takes time and effort to find an appropriate setting condition.

### <Configuration and Operation of Charged Particle Beam System, and Optical Axis Adjustment Method>

Hereinafter, a configuration and an operation of a charged particle beam system capable of appropriately setting a wobbler condition, and an optical axis adjustment method will be described.

As one aspect, the charged particle beam system capable of appropriately setting a wobbler condition includes an optical element group and at least one computer system configured to control the optical element group. The optical element group includes a scanning deflector configured to perform scanning with a beam emitted from a charged particle source, a lens configured to focus the beam, and a (alignment) deflector configured to deflect a trajectory of the beam to be incident on the lens. In the charged particle beam system, an image obtained by irradiating a sample with the beam is displayed on a display device. The one or more computer systems cause the display device to display, in accordance with a size of a region selected by a selection device (a pointing device or the like) for selecting any region of an image, a frame indicating a selection region, and an input field for inputting at least one condition of the change time when changing a lens condition of a lens by (i) a scanning speed or (ii) a predetermined change width. According to the charged particle beam system, an operator can easily search for a setting condition under which the wobbler adjustment is possible, and the adjustment workability is greatly improved.

In the following description, an SEM system as an aspect of the charged particle beam system will be described as an example, and the charged particle beam system is not limited thereto and can be applied to, for example, an FIB-SEM or a scanning transmission electron microscope (STEM). In all the following drawings, components having the same function are denoted by the same reference signs, and repeated description thereof is omitted.

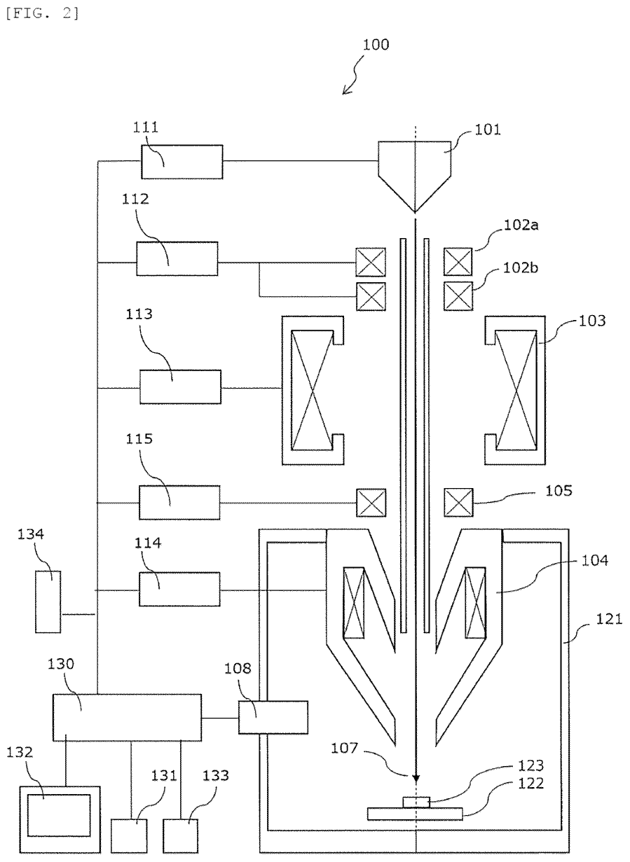

FIG. 2 is a diagram illustrating a schematic configuration example of an SEM system 100 according to the embodiment. The SEM system 100 includes an electron beam source 101, an alignment deflector 102, a focusing lens 103, an objective lens 104, and optical elements such as a scanning deflector 105. An electron beam 107 emitted from the electron beam source 101 passes through the components and irradiates a sample 123.

The optical elements are controlled by an electron beam source control unit 111, an alignment deflector control unit 112, a focusing lens control unit 113, an objective lens control unit 114, and a scanning deflector control unit 115. The sample 123 is placed on a sample stage 122 disposed in a vacuum chamber 121. The electron beam 107 is focused by the focusing lens 103 and the objective lens 104, and the sample 123 is scanned with the electron beam 107 by the scanning deflector 105. At this time, secondary electrons and backscattered electrons are emitted from a surface of the sample 123, and are detected by a detector 108.

An integrated computer 130 is implemented by one or more computer subsystems, and controls the components of the SEM and executes image generation (image processing) based on an output of the detector. The one or more computer systems include a storage medium in which a program for executing image processing and device control described later is stored, a processor for executing the program, and the like. Specifically, the integrated computer 130 controls the control units 111 to 115 of the respective optical elements and performs image generation based on the output of the detector 108.

A controller 131 (an input device such as a pointing device like a keyboard or a mouse), an image display device 132, and the like are connected to the integrated computer 130. An operator inputs control information such as irradiation conditions of a beam (hereinafter, referring to an electron beam in the SEM system 100) to the integrated computer 130 from the controller 131. The integrated computer 130 controls the components in the SEM system 100 according to the input information. Further, the integrated computer 130 causes the image display device 132 to display a beam irradiation condition input together with an SEM image and a designated region on the SEM image by a pointing device or the like. The image display device may be, for example, a stationary display device (display) or a tablet-type display device, and the type thereof is not limited.

An aberration increases in the beam that is a beam passing through the focusing lens 103 and the objective lens 104 through a position deviated from the ideal optical axis of the optical elements. As the aberration decreases, the electron beam can be narrowed down. Therefore, in order to observe the sample 123 with higher resolution, it is necessary to perform the optical axis adjustment by which the beam passes through the ideal optical axis.

As described above, performing the adjustment of periodically changing the excitation of the lens to be subjected to the optical adjustment is particularly referred to as a wobbler. The alignment deflector 102 for wobbler adjustment is controlled by an X alignment deflector 102a for deflecting a charged particle beam in an X-axis direction and a Y alignment deflector 102b for deflecting the charged particle beam in a Y-axis direction. By combining the alignment deflectors 102a and 102b, the electron beam can be deflected two-dimensionally. In the embodiment, an example in which an optical element to be subjected to the optical axis adjustment is an electromagnetic lens will be mainly described, and another lens such as an electrostatic lens or another optical element such as an astigmatic corrector may be used. A different alignment deflector may be provided for each optical element. In the embodiment, an optical axis direction is defined as a Z direction.

In the wobbler, a wobbler signal for periodically changing excitation is transmitted by the integrated computer 130 to the focusing lens 103 and the objective lens 104 to be adjusted, and a lens focusing action is periodically changed. When the electron beam passes through the ideal optical axis of the lens to be adjusted, the electron beam passes through the lens vertically, and thus during the wobbler operation, the focusing position of the lens changes periodically in the optical axis (Z) direction from the sample surface, but does not move in the X and Y directions. Accordingly, a center position of an observation image does not change, and image blurring occurs periodically.

On the other hand, when the beam passes through a position deviated from the ideal optical axis of the lens, the beam obliquely passes through the lens, and thus during the wobbler operation, the focusing position of the lens changes in the Z direction as well as in the X and Y directions. Accordingly, when the center position of the observation image repeatedly reciprocates in a predetermined direction, image blurring occurs periodically.

In the wobbler adjustment, the operator observes periodic image movement and adjusts the alignment deflectors 102a and 102b by the alignment deflector control unit 112 so as to reduce the image movement, thereby controlling the beam to pass through the ideal optical axis.

Strictly speaking, adjustment values of the alignment deflectors 102a and 102b at the time of the wobbler adjustment differ depending on the focusing position of the lens, that is, the surface height of the observation sample (the sample 123). This is because the ideal optical axis of the lens changes depending on the focusing position of the lens. The sample to be observed in the charged particle beam system includes a sample having a height difference (a positional difference in the Z direction). Therefore, the sample height may change at the observation position and a position away from the observation position. For this reason, by setting the field of view for the wobbler adjustment in the vicinity of the observation position (field of view) or at a position at which the height is regarded as the same level as that of the observation position, it is possible to accurately evaluate the image shake at the time of wobbling. For example, particularly in processing and observation with the FIB, when the sample is placed on a mesh or lamella, the sample surface is inclined with respect to the optical axis. Therefore, the sample height changes at the observation position and a position away from the observation position. For this reason, it is desirable to perform the wobbler adjustment in the vicinity of the observation position or the like.

Further, since the sample 123 to be observed by the SEM system 100 includes a sample having a characteristic of being susceptible to beam irradiation, it is desirable to perform the beam irradiation for the wobbler adjustment at a position different from the observation position in order to reduce the beam irradiation amount per unit area.

As described above, it is desirable to perform the wobbler adjustment at a position different from the observation position but having the same condition as the observation position. In order to achieve this, it is desirable to generate an image from which the operator selects a beam scanning region at the time of the wobbler adjustment.

### <Regarding Wobbler Selection Region>

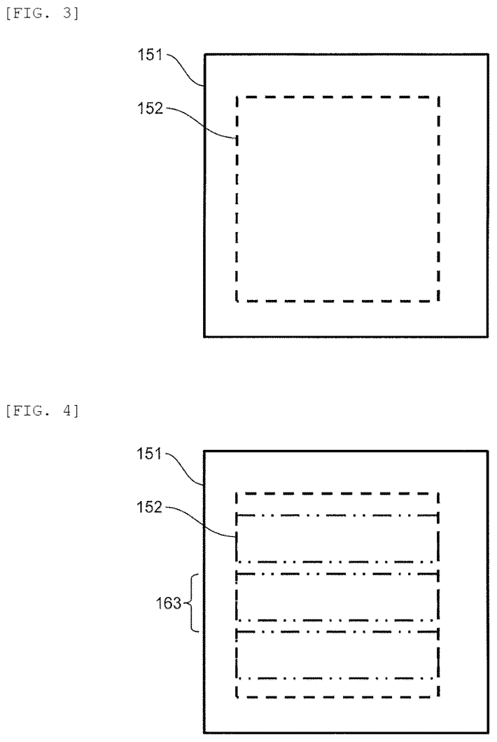

FIG. 3 is a diagram illustrating an example in which a frame (region 152: a partial region) indicating a wobbler selection region is superimposed and displayed on an initial screen 151 (first image). The frame (region 152) can be set in any position and size by a pointing device or the like. Specifically, the operator selects a scanning region (region 152) by using a selection device (pointing device or the like) 133 that selects any region in the initial screen 151. The selection region is a wobbler scanning region. Then, the integrated computer 130 controls the scanning deflector control unit 115 such that a region corresponding to the wobbler scanning region in the initial screen 151 is scanned with the beam.

The initial screen 151 for performing the region selection (setting the region 152) is image data acquired before scanning the region 152 and stored in the storage medium, and is obtained by scanning a region larger than the wobbler scanning (selection) region. Note that a time corresponding to one period of the lens excitation change is referred to as a wobbler time, and a time required for the beam to scan the selection region is referred to as a frame time.

The frame display as illustrated in FIG. 3 is performed, and the scanning deflector 105 is controlled to selectively perform beam scanning in the frame (region 152) to generate an image, and by performing wobbling in this state, an image of the region 152 can be visually checked.

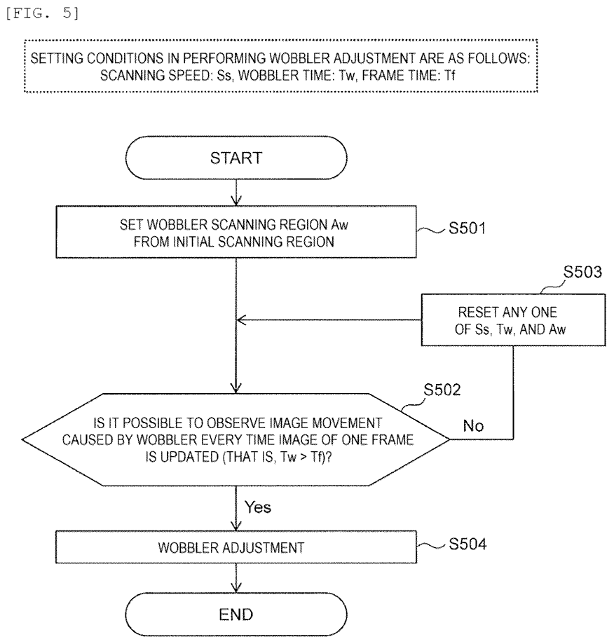

According to a user interface as illustrated in FIG. 3, when wobbling is performed in the region 152 set at any position and size, a periodically blurred region image may be generated while a wobbler adjustment image can be visually evaluated (see FIG. 4).

### <Blurred Image Region Generated at Time of Wobbler Adjustment>

FIG. 4 is a diagram illustrating an example of a state in which an in-focus image region and an out-of-focus region, in which the image is blurred, periodically appear in the wobbler adjustment image (region 152). By the wobbling of the electromagnetic lens, a focus state periodically varies. In the example in FIG. 4, an in-focus region 401 and an out-of-focus region 402 appear alternately, and a striped pattern seems to appear in the region 152. In such a state, the image shake may not be appropriately evaluated. The striped pattern is generated when at least one of the settings of the size of the wobbler scanning region, the scanning speed, and the wobbler time is inappropriate.

In a case where the frame time is set to be earlier than the wobbler time, the striped pattern as described above is not generated, and the wobbler adjustment can be performed by the operator observing the image movement.

On the other hand, when the frame time is set to be delayed with respect to the wobbler time, a focus change occurs a plurality of times in one frame, and thus a striped pattern as illustrated in FIG. 4 is generated. That is, the image movement cannot be observed as image change for each frame, and the image adjustment is difficult.

From the above, it is desirable to shorten the frame time with respect to the wobbler time as a generation condition of the wobbler adjustment image. In order to perform such setting, first, it is conceivable to set the size of the wobbler scanning region to be smaller than that in the state where the striped pattern is generated. For example, in the case of an SEM system configured such that the frame time changes in proportion to a frame area (size of the scanning region) at the time of setting the wobbler region, if the area of the wobbler scanning region is reduced, the frame time can be shortened compared to that before reducing the region. Note that restricting the region in the initial screen 151 to be small from the initial scanning region to the wobbler scanning region is achieved by reducing the beam scanning range of the scanning deflector to be small from a predetermined scanning width. This is different in principle from changing the focusing position of the lens to increase an observation magnification and reducing the scanning region on the sample.

Further, in order to shorten the frame time with respect to the wobbler time, it is conceivable to set the scanning speed of the beam to be higher than that in the state where the striped pattern is generated. Since the frame time is shortened in inverse proportion to the scanning speed, if the scanning speed is increased, it is possible to shorten the frame time compared to that before increasing the speed. Further, in order to shorten the frame time with respect to the wobbler time, it is conceivable to set the wobbler time to be longer than that in the state where the striped pattern is generated.

### <Wobbler Condition Setting Processing>

FIG. 5 is a flowchart illustrating setting processing of wobbler conditions in the SEM system (charged particle beam system) 100 including the user interface as illustrated in FIG. 3.

The integrated computer 130 is implemented by one or more computer subsystems, and includes a storage medium in which a program for displaying a user interface on the image display device 132 is stored. Here, a scanning speed Ss, a wobbler time Tw, and a frame time Tf are set as setting conditions when performing the wobbler adjustment. As long as Tw<Tf is satisfied in the wobbler scanning region 152 selected by the operator, appropriate wobbler conditions are not set.

Although it is possible to appropriately perform the optical axis adjustment by appropriately setting the combination of a plurality of parameters, it is desirable that the combination of the parameters is various and the setting is performed according to a sample state in the initial screen 151.

In FIG. 5, when the operator sets a wobbler scanning region Aw from the initial scanning region, the integrated computer 130 accepts the setting performed by the operator (step 501).

When the operator inputs (observation result) whether the image movement due to the wobbler can be observed (Tw>Tf) every time the image of one frame is updated, the integrated computer 130 performs determination regarding the observation result from the operator. If the observation result is that “the image movement can be observed (Tw>Tf)” (Yes in step 502), the processing proceeds to step 504. On the other hand, if the observation result is that “the image movement cannot be observed (Tw≤Tf)” (No in step 502), the processing proceeds to step 503.

In step 503, the integrated computer 130 performs notification of prompting the operator to reset any one of the scanning speed Ss, the wobbler time Tw, and the frame time Tf, and accepts at least any one of Ss, Tw, and Aw reset by the operator according to the notification. Then, the integrated computer 130 performs the wobbler adjustment (step 504).

### (2) Embodiments

The outline of the setting processing of the wobbler conditions has been described above, and embodiments of the SEM system (charged particle beam system) 100 capable of easily setting appropriate conditions will be described in more detail below.

### Embodiment 1

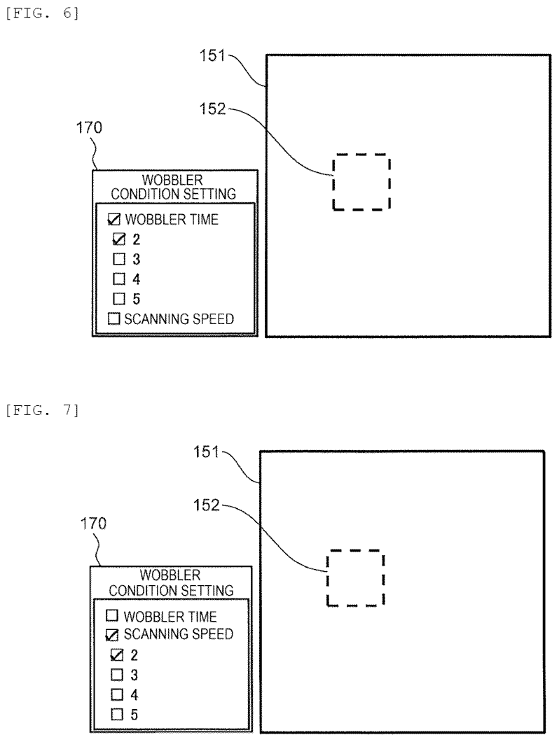

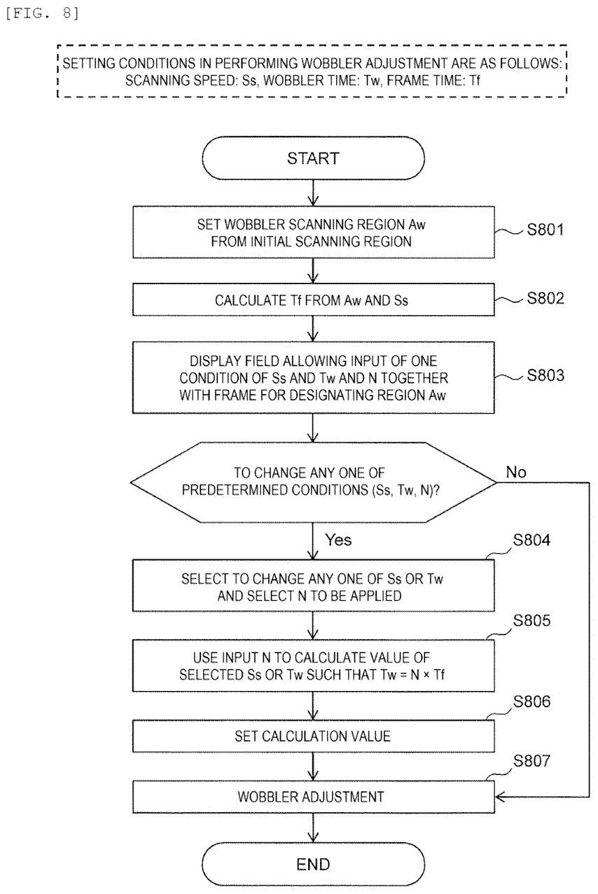

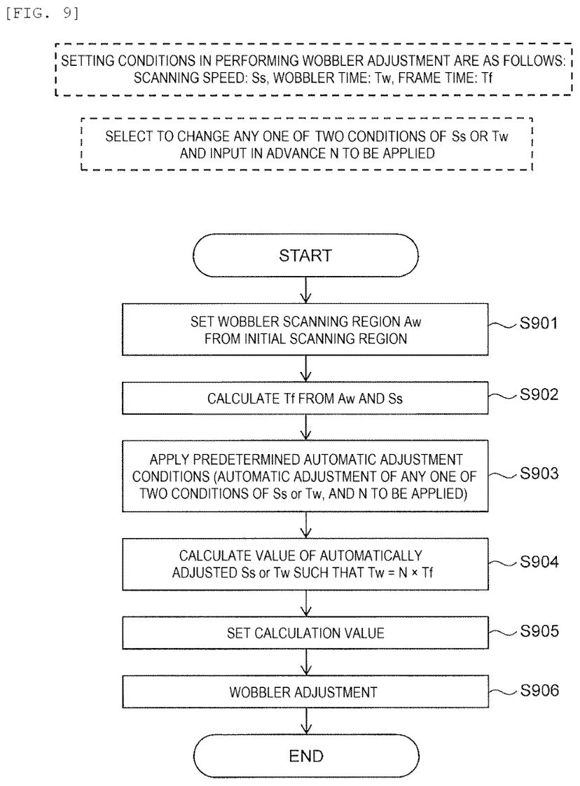

FIGS. 6 and 7 are diagrams illustrating an example of a GUI screen for setting the wobbler conditions. FIG. 8 is a flowchart for illustrating setting processing using the user interface.

Using the SEM system (charged particle beam system) 100, first, an initial scanning region is set so as to include a region to be observed, and the initial screen 151 is acquired. The integrated computer 130 stores image data regarding the initial screen 151 in a predetermined storage medium and displays the image data on a GUI screen as illustrated in FIG. 6 or FIG. 7. When the operator sets the wobbler scanning region Aw (region 152) on the initial screen 151 displayed on the GUI screen, the integrated computer 130 accepts the setting performed by the operator (step 801).

The integrated computer 130 calculates a scanning time per frame based on size information on a range of the wobbler scanning region 152 at the time of the wobbler adjustment and based on an initially set scanning speed (step 802).

When the operator selects a scanning region by using the selection device (pointing device or the like) 133, the integrated computer 130 displays an input field 170 of at least one of the wobbler time and the scanning speed together with a frame for designating the wobbler scanning region 152 on the screen of the image display device 132 (step 803). At this time, the integrated computer 130 may also display an input field for setting a wobbler adjustment coefficient (hereinafter, referred to as N). The input field 170 may be automatically displayed together with the frame for designating the region 152, or may be manually displayed by a simple operation (mouse click or keyboard key input) by using the selection device (pointing device or the like) 133. The wobbler adjustment coefficient N is a natural number of 2 or larger.

When the operator selects the change of the scanning speed or the change of the wobbler time, the integrated computer 130 selects a condition to be changed from the two conditions and a value of N (step 804).

The integrated computer 130 uses the value of N selected in step 804 to calculate and apply a value of the selected scanning speed or a value of the selected wobbler time by the wobbler condition adjustment unit 134 such that “the frame time×N=the wobbler time” (steps 805, 806, and 807).

The wobbler condition adjustment unit 134 can store the value of N as a table for each observation condition, and by using N as a default value, the work of setting the value of N by the operator can be omitted.

Further, by allowing the operator to freely set the value of N, it is possible to further improve the workability of the wobbler adjustment. A signal to noise ratio (S/N ratio) of an observation image changes according to condition (i) a beam irradiation time (dwell time) per pixel, condition (ii) a beam irradiation amount (dose amount) per pixel, condition (iii) a ratio (yield) of an electron amount of an incident beam to an electron amount emitted from a sample, condition (iv) a ratio (detection efficiency) of electrons detected by a detector to electrons emitted from a sample, and the like.

The operator indirectly sets the condition (i) by setting the scanning time or the like according to the observation purpose or the like. Since the conditions (ii) to (iv) change according to the setting of the condition (i), the conditions (ii) to (iv) also change according to the preference of the operator. In other words, there is a possibility that the frame time in reverse proportion to the scanning speed changes for each operator.

On the other hand, with respect to the wobbler time, there is an appropriate period of the image movement that can be easily adjusted by the operator. Therefore, depending on the operator, there are various frame times, and there is a range of appropriate values of the wobbler time. It is desirable that various settings of N are enabled. As described above, the operability is improved by allowing the operator to freely set the value of N according to each observation condition.

With the configuration in which the setting of the region 152 can be performed on the user interface and the input field 170 is displayed in a state in which it is possible to visually determine whether a striped pattern appears in the region 152, selection of a region suitable for wobbling and condition setting for wobbling can be performed together. In order to enable such setting, for example, a configuration is conceivable in which one of a plurality of buttons provided in the pointing device is set as a button for selecting a top portion of a frame when selecting the region 152, and another button is set as a display button of the input field 170 (the input field 170 is displayed by pressing the button). After the setting of the region 152, the input field 170 may be automatically displayed.

It is desirable that control by an adjustment knob of the alignment deflector is enabled so that the alignment can be quickly performed after appropriate selection of the region 152 and the wobbling condition setting.

FIGS. 6 and 7 show examples of an input portion in which the scanning speed and the wobbler time are not directly input but replaced with other parameters that change according to the scanning speed and the wobbler time, such as 2, 3, 4, and so on. Alternatively, an input field may be provided in which the scanning speed and wobbler time can be directly input, or an input portion may be provided in which the scanning speed and wobbler time can be adjusted by changing the position of a knob such as a control bar.

### Embodiment 2

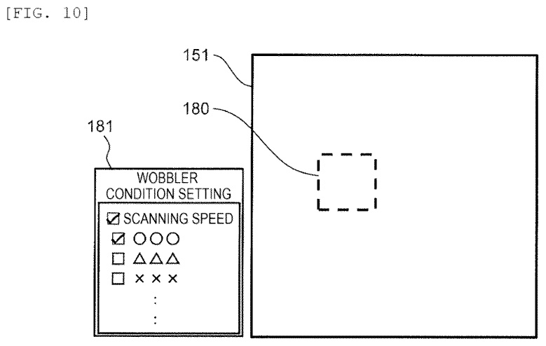

FIG. 9 is a flowchart illustrating processing of performing the optical axis adjustment by using the SEM system (charged particle beam system) 100 including the user interface.

The integrated computer 130 calculates the scanning time per frame based on the size of the wobbler scanning region 152 and the scanning speed at the time of the wobbler adjustment. When the operator selects the scanning region by the selection device (pointing device or the like) 133, if the wobbler scanning region 152 is designated on the image display device 132, the integrated computer 130 accepts the designation of the wobbler scanning region 152 (step 901).

The integrated computer 130 calculates the frame time Tf based on the size information Aw of the wobbler scanning region and the scanning speed Ss set as an initial value (step 902). A memory built in the integrated computer 130 stores, for example, Tf=Aw×Ss×n (n being a predetermined coefficient) in advance, and the integrated computer 130 calculates Tf that increases in proportion to the size of Aw.

Next, the integrated computer 130 reads a preset condition (a parameter and a coefficient to be adjusted to satisfy Tw=N×Tf) from the memory, and obtains a parameter satisfying Tw=N×Tf (step 903 to step 904).

The integrated computer 130 sets (automatically sets) parameters obtained by the calculation, and controls the optical elements (the scanning deflector, the objective lens, the alignment deflector, and the like) provided in a charged particle beam device so as to perform the wobbler adjustment (step 905 to step 906). The automatic setting of the parameters is implemented by the wobbler condition adjustment unit 134 based on a calculation result of the integrated computer 130 so that “the frame time×N=the wobbler time” or “the frame time×N<the wobbler time<a predetermined time” is satisfied. Here, N is the wobbler adjustment coefficient and is a natural number of 2 or larger.

The wobbler condition adjustment unit 134 stores the value of N as a table for each observation condition, and stores which of the two conditions is automatically set so that the above expression is satisfied. The stored value can be changed in advance for the wobbler adjustment work. Accordingly, for the same reason as described in Embodiment 1, it is possible to appropriately perform the wobbler condition setting for the observation condition for each operator. An input screen for the condition setting is not displayed together with the frame for designating the wobbler scanning region 152 for each wobbler adjustment, but is implemented by the operator as a work separate from the wobbler adjustment work. Accordingly, it is possible to reduce the occurrence that the input field is displayed every time the wobbler adjustment is performed, and to shorten the operation by automation.

In the embodiment, an example has been described in which arithmetic expressions including the frame time and the wobbler time are used to obtain the other based on the input of one. Instead of the arithmetic expressions, a relationship table may be stored in a predetermined storage medium as related information of the two parameters, and the other may be obtained by referring to the relationship table.

### Embodiment 3

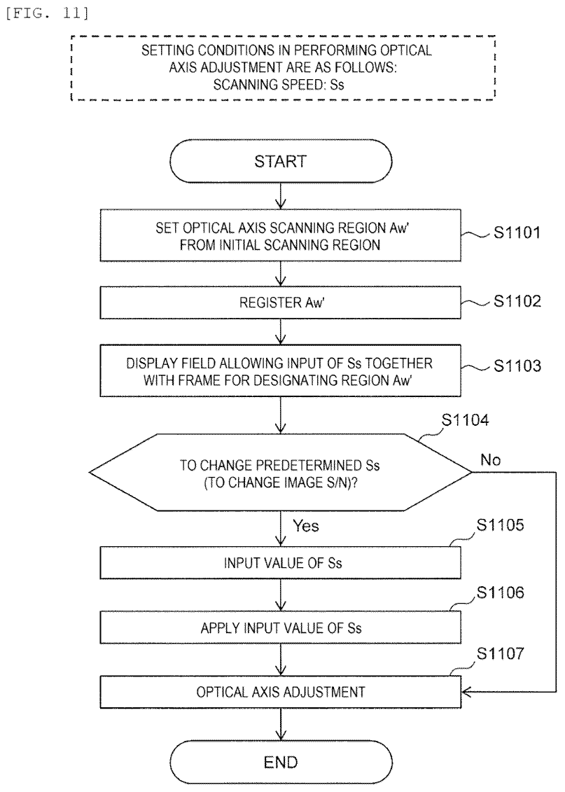

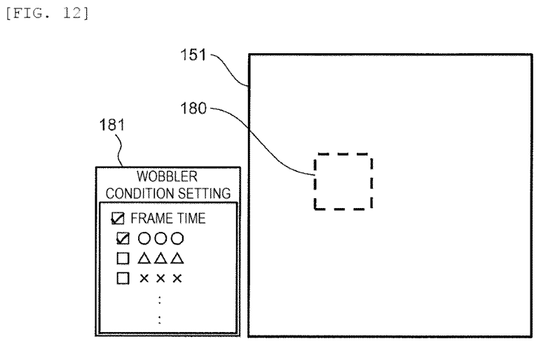

FIG. 10 is a diagram illustrating a configuration example of a user interface according to Embodiment 3. FIG. 11 is a flowchart illustrating an example of optical axis adjustment processing in which the user interface illustrated in FIG. 10 is used.

When settings of an optical axis adjustment scanning (selection) region 180 (Aw′) on the GUI screen (FIG. 10) displaying the initial screen 151 performed by the operator are accepted (step 1101), the integrated computer 130 registers a shape and a position of the optical axis adjustment scanning (selection) region 180 in an internal memory (not shown) (step 1102). The optical axis adjustment scanning (selection) region 180 is used as a scanning region in the subsequent optical axis adjustment.

The integrated computer 130 displays an input field 181 for inputting a scanning speed on the image display device 132 together with a frame for designating the optical axis adjustment scanning (selection) region 180 selected by the operator (step 1103). The input field 181 may be automatically displayed together with the frame for designating the optical axis adjustment scanning (selection) region 180, or may be manually displayed in response to a simple operation (mouse click or keyboard key input) associated with an operation of the selection device (pointing device or the like) 133 for designating the optical axis adjustment scanning (selection) region 180. In Embodiments 1 and 2 described above, an example in which the operator observes the image movement caused by the wobbler at the time of the optical axis adjustment and the operator manually adjusts the beam irradiation axis is described. On the other hand, in automatic optical axis adjustment, it is desirable to perform the adjustment based on image movement occurring when excitation of a lens is changed in a specific change step without performing the wobbler (without performing a periodic change in excitation of the lens). However, in any of the manual optical axis adjustment and the automatic optical axis adjustment described above, it is desirable to secure an S/N ratio sufficient for recognizing the presence of image shake and parallax with high accuracy in an image used at the time of image adjustment. The S/N of the image depends on the beam irradiation time per pixel, that is, the scanning speed.

The operator evaluates the S/N of an image in the registered optical axis adjustment scanning (selection) region 180, and inputs an instruction on whether to change to the defined scanning speed Ss to the integrated computer 130. When the instruction from the operator indicates the use of a default value as the scanning speed (No in step 1104), the integrated computer 130 shifts the processing to step 1107. When the instruction from the operator indicates the use of a desired input value as the scanning speed (Yes in step 1104), the integrated computer 130 shifts the processing to step 1105.

When the operator inputs the scanning speed to the input field 181 so that the S/N is an appropriate value, the integrated computer 130 accepts the input value of the scanning speed (step 1105) and applies the input value of the scanning speed (step 1106).

The integrated computer 130 sets an input value or a default value of the scanning speed as a parameter and controls each optical element (a scanning deflector, an objective lens, an alignment deflector, and the like) provided in a charged particle beam device so as to perform the optical axis adjustment (step 1107).

As described above, according to Embodiment 3, since the scanning speed is set to the default value, an operation of inputting the scanning speed by the operator can be omitted. Further, when the S/N is not appropriate, the scanning speed can be freely set by the operator, so that the scanning speed can be set to the S/N desired by the operator.

Normally, when displaying the input field every time the scanning speed is to be input, it is necessary to move the mouse to the button. In contrast, according to the charged particle beam system 100 configured to execute the flowchart illustrated in FIG. 11, it is possible to reduce the time and effort of moving the mouse and simplify the work.

### Embodiment 4

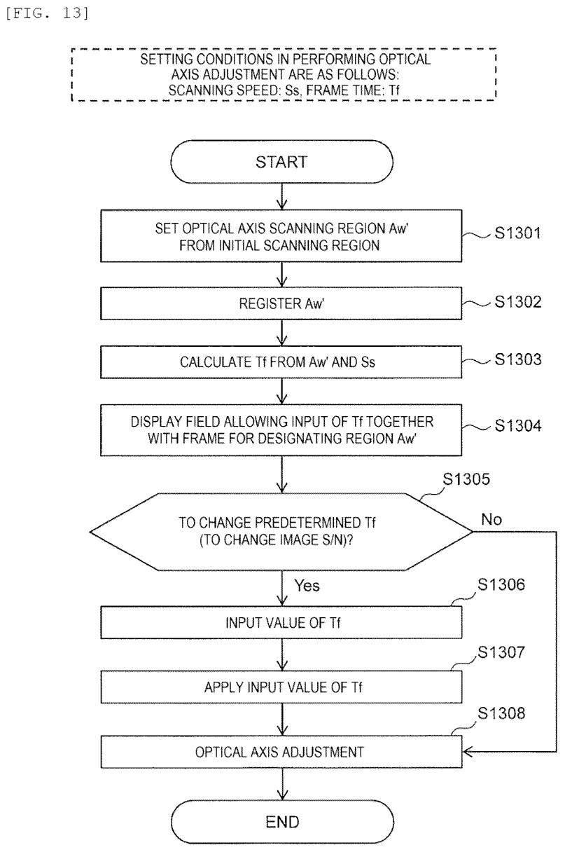

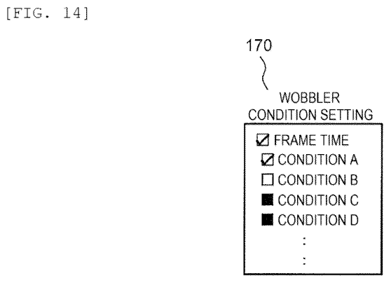

FIG. 12 is a diagram illustrating a configuration example of a user interface according to Embodiment 4. FIG. 13 is a flowchart illustrating optical axis adjustment processing in which the user interface illustrated in FIG. 12 is used.

When the operator selects (sets) the optical axis adjustment scanning (selection) region 180 (Aw′) using the selection device (pointing device or the like) 133 (step 1301), the integrated computer 130 accepts the selection (setting), registers a shape and a position of the optical axis adjustment scanning (selection) region 180 in an internal memory, and uses the optical axis adjustment scanning (selection) region 180 as the scanning region in the subsequent optical axis adjustment (step 1302).

The integrated computer 130 calculates the frame time based on the range of the optical axis scanning (selection) region 180 and the scanning speed at the time of the optical axis adjustment (step 1303).

The integrated computer 130 displays the input field 181 for inputting the frame time on the image display device 132 together with a frame for designating the optical axis adjustment scanning (selection) region 180 selected by the operator (step 1304). The input field 181 may be automatically displayed together with the frame for designating the optical axis adjustment scanning (selection) region 180, or may be manually displayed in response to a simple operation (mouse click or keyboard key input) associated with an operation of the selection device (pointing device or the like) 133 for designating the optical axis adjustment scanning (selection) region 180.

Since the S/N ratio of an image depends on the scanning speed and the frame time depends on the scanning speed, the S/N ratio of the image can be adjusted with the frame time. The operator observes the S/N ratio in the registered optical axis adjustment scanning (selection) region 180, determines whether to use a default value of the frame time for the optical axis adjustment or to change the default value and use a desired input value for the optical axis adjustment, and inputs an instruction to the integrated computer 130. When the instruction from the operator indicates the use of the default value as the frame time (No in step 1305), the integrated computer 130 shifts the processing to step 1308. When the instruction from the operator indicates the use of a desired input value as the frame time (Yes in step 1305), the integrated computer 130 shifts the processing to step 1306.

When the operator inputs the frame time in the input field 181 so that the S/N ratio is an appropriate value, the integrated computer 130 accepts the input value (step 1306) and applies the input value (step 1307).

The integrated computer 130 sets an input value (a desired value of the operator) or a default value of the frame time as a parameter, and controls each optical element (a scanning deflector, an objective lens, an alignment deflector, and the like) provided in a charged particle beam device so as to perform the optical axis adjustment.

As described above, according to Embodiment 4, by using the default value as the input value of an m frame time, an operation of inputting the frame time by the operator can be omitted. Further, by allowing the operator to freely set the frame time, the frame time can be set so as to obtain a desired S/N ratio.

Normally, it is necessary to move the mouse each time to the button for displaying an input field for changing the image S/N ratio. On the other hand, according to the charged particle beam system configured to execute the flowchart illustrated in FIG. 13, it is possible to reduce the time and effort of moving the mouse and simplify the work.

### Embodiment 5

In Embodiment 5, the charged particle beam system 100 having a function of notifying an operator whether a setting of the wobbler scanning region 152 is appropriate based on the setting will be described.

If the wobbler scanning region 152 is not set within a region at substantially the same height as an observation region, it may be impossible to perform appropriate evaluation of image shake. Further, if there is no edge or the like allowing to specify positions in at least two directions (x and y directions) in the field of view, it is not possible to evaluate two-dimensional image shake.

When the wobbler scanning region 152 is set, it is possible to determine whether the setting is appropriate or inappropriate based on evaluation of a signal amount in the wobbler scanning region 152, evaluation of the presence or absence of an edge in which image processing is used, and the like. For example, if the integrated computer 130 notifies the operator by generating an error message for notifying the result, changing the color of the frame of the region 152, or the like, it is possible to reduce the operation time required until an appropriate condition is set.

For example, when the region 152 in FIG. 4 is set, an image is formed by performing beam scanning on the region, and then an obtained signal amount (secondary electron detection amount) is small, there is a possibility that sufficient contrast cannot be obtained. Accordingly, the integrated computer 130 evaluates the output of the detector 108. When the signal amount is equal to or less than a predetermined value (a preset threshold), for example, the integrated computer 130 displays a message for prompting a decrease in the scanning speed, or displays a message (alarm) for prompting a countermeasure (for example, increasing a beam current) to increase the signal amount. Accordingly, the operator can recognize that there is a possibility that the wobbling fails, and can quickly perform appropriate setting.

Further, also in a case where an edge or the like for evaluating image shake is not present or is not sufficient in the region 152, there is a possibility that the wobbling fails. In such a case, the integrated computer 130 may display a message for prompting the operator to reset the scanning region at a position where an object with clear contrast is present. The integrated computer 130 may notify the operator of the possibility of a wobbling failure by setting the color of the frame of the region 152 to a color indicating a warning (yellow, red, or the like (green display in case of an appropriate setting)). Whether contrast in the X direction and contrast in the Y direction are clear may be determined by, for example, a method of creating luminance profiles in two directions and determining whether a luminance difference between the highest luminance and the lowest luminance is a predetermined value or more, or may be determined by another contrast evaluation method.

Also in a case where a striped pattern is generated in the region 152, there is a possibility that the evaluation using wobbling fails. When the region 152 is determined, the initial value of the frame time is determined accordingly. Therefore, for example, the integrated computer 130 determines whether “the frame time<the wobbler time (initial value)” is satisfied. When this condition is not satisfied, the integrated computer 130 can notify that appropriate setting is not performed, by performing at least one of display of a message prompting to reduce the scanning time (increase the scanning speed) (or increase the wobbler time), display (identification display) different from that when appropriate setting is performed on the region 152, and the like. As a method of determining the presence or absence of a striped pattern, the presence or absence of a striped pattern can also be determined by evaluating a spatial frequency of the region 152 in the Y direction (longitudinal direction) by the integrated computer 130 and determining whether a region having a low spatial frequency (an out-of-focus region in which an image is blurred) and a region having a high spatial frequency (a state in which a structure of a sample is clearly expressed due to being in focus) appear alternately.

Since an initial generation condition of the image required for wobbling is determined by the setting of the region 152 as described above, the suitability of the image is evaluated in that state and an appropriate message is output, whereby it is possible to quickly perform appropriate setting.

It is also conceivable to prohibit setting which leads to a state in which a striped pattern is mixed into the region 152 or a striped pattern affects appropriate image evaluation. FIG. 14 is a diagram illustrating a configuration example of a wobbler condition setting screen (GUI). In the wobbler condition setting screen illustrated in FIG. 14, a check box of the frame time is selected and the input is prohibited so that conditions C and D cannot be selected (cannot be checked). The integrated computer 130 displays image generation conditions on the GUI screen such that selection of an image generation condition under which a striped pattern is mixed in the region 152 is not allowed. In this way, it is possible to prevent image generation that may lower the accuracy of axis misalignment evaluation.

### (3) Others

(v) Functions of the embodiment can also be implemented by a software program code. In this case, a storage medium that records the program code is provided in a system or a device, and a computer (or CPU or MPU) of the system or the device reads the program code stored in the storage medium. In this case, the program code itself read from the storage medium implements the functions of the above-described embodiment, and the program code itself and the storage medium that stores the program code implement the present disclosure. Examples of the storage medium for supplying such a program code include a flexible disk, a CD-ROM, a DVD-ROM, a hard disk, an optical disk, a magneto-optical disk, a CD-R, a magnetic tape, a nonvolatile memory card, and a ROM.

An operating system (OS) or the like operating on a computer may perform a part or all of actual processing based on an instruction of the program code, and the functions of the above-described embodiments may be implemented by the processing. Further, after the program code read from the storage medium is written in a memory on the computer, a CPU or the like of the computer may perform a part or all of actual processing based on an instruction of the program code, and the functions of the above-described embodiments may be implemented by the processing.

Further, the software program code for implementing the functions of the embodiments may be stored, by distributing via a network, in a storage unit such as a hard disk or a memory of the system or the device or a storage medium such as a CD-RW or a CD-R, and the computer (or CPU or MPU) of the system or the device may read and execute the program code stored in the storage unit or the storage medium at the time of use.

The processes and techniques described here do not essentially relate to any specific device, and can be implemented by a combination of suitable components. Further, in order to execute the steps of the method described here, a dedicated device may be constructed. Various technical elements can be formed by appropriately combining a plurality of components disclosed in the embodiment. For example, several components may be deleted from all components disclosed in the embodiment. Although the present disclosure has been described with reference to specific examples, all the specific examples are not intended to limit the present disclosure but to facilitate understanding. Those skilled in the art will readily recognize that there are numerous combinations of hardware, software, and firmware that are suitable for implementing the techniques of the present disclosure. For example, the above-described software can implement the techniques of the present disclosure in a wide range of programs or script languages such as assembler, C/C++, perl, Shell, PHP, and Java (registered trademark).

Further, control lines and information lines considered to be necessary for description are shown in the above-described embodiments, and not all control lines and information lines in a product are necessarily shown. All configurations may be connected to one another.

In addition, other implementations of the present disclosure will be apparent to those skilled in the art from consideration of the description and embodiments of the present disclosure disclosed herein. The contents and specific examples of the description are merely typical, and the scope and spirit of the present disclosure are indicated by the following claims.

### REFERENCE SIGNS LIST

101: ELECTRON BEAM SOURCE
102: ALIGNMENT DEFLECTOR
102a: X ALIGNMENT DEFLECTOR
102b: Y ALIGNMENT DEFLECTOR
103: FOCUSING LENS
104: OBJECTIVE LENS
105 SCANNING DEFLECTOR
107: ELECTRON BEAM
108: DETECTOR
111: ELECTRON BEAM SOURCE CONTROL UNIT
112: ALIGNMENT DEFLECTOR CONTROL UNIT
113: FOCUSING LENS CONTROL UNIT
114: OBJECTIVE LENS CONTROL UNIT
115: SCANNING DEFLECTOR CONTROL UNIT
121: VACUUM CHAMBER
122: SAMPLE STAGE
123: SAMPLE
130: INTEGRATED COMPUTER
131: CONTROLLER
132: IMAGE DISPLAY DEVICE
133: SELECTION DEVICE
134: WOBBLER CONDITION ADJUSTMENT UNIT
151: INITIAL SCREEN
152: WOBBLER SCANNING REGION
163: IMAGE MOVEMENT
170: INPUT FIELD
180: OPTICAL AXIS ADJUSTMENT SCANNING (SELECTION) REGION
181: INPUT FIELD

1.-11. (canceled)

12. A charged particle beam system comprising:
a charged particle beam column including
a scanning deflector configured to perform scanning with a beam emitted from a charged particle source,
an optical element configured to adjust the beam, and
an adjustment deflector configured to adjust a trajectory of the beam incident on the optical element; and
one or more computer subsystems connected to the charged particle beam column and configured to control the scanning deflector and the adjustment deflector, wherein
the one or more computer subsystems include a user interface configured to display an image output from the charged particle beam column and a partial region of the image selected by a user,
the one or more computer subsystems
periodically change an optical condition of the optical element,
generate an image based on a signal output from the charged particle beam column when the optical condition of the optical element is periodically changed, and
display, on the user interface, an input portion for allowing a user to set at least one of the generated image, the partial region, a first parameter relating to a scanning speed of the scanning deflector, or a second parameter relating to a change speed of the optical element, and
after one of the first parameter and the second parameter is set, the one or more computer subsystems identify, in the other parameter, a parameter not satisfying a predetermined condition and a parameter satisfying the predetermined condition and display the identified parameters on the user interface.

13. The charged particle beam system according to claim 12, wherein
the one or more computer subsystems display an image of a region larger than the partial region and an image of the partial region on the user interface in a superimposed manner.

14. The charged particle beam system according to claim 13, wherein
the image of the partial region and the image of the region larger than the partial region are obtained by different scans of the scanning deflector.

15. The charged particle beam system according to claim 12, wherein
the one or more computer subsystems calculate a scanning time per frame based on a partial region and the first parameter set on the user interface.

16. The charged particle beam system according to claim 15, wherein
the one or more computer subsystems issue an alarm when a change time of one period of the optical element is shorter than a time per frame.

17. The charged particle beam system according to claim 15, wherein
when a change time of one period of the optical element is shorter than a time per frame, the one or more computer subsystems cause the user interface to display a message for prompting to increase the scanning speed.

18. The charged particle beam system according to claim 15, wherein
when a change time of one period of the optical element is shorter than a time per frame, the one or more computer subsystems cause the user interface to display a message for prompting to increase the change time of one period of the optical element.

19. The charged particle beam system according to claim 15, wherein
on the user interface, input of at least one of the first parameter and the second parameter by which a change time of one period of the optical element is longer than a time per frame is allowed, and input of at least one of the first parameter and the second parameter by which the change time of one period of the optical element is shorter than the time per frame is prohibited.

20. A charged particle beam system comprising:
a charged particle beam column including
a scanning deflector configured to perform scanning with a beam emitted from a charged particle source,
an optical element configured to adjust the beam, and
an adjustment deflector configured to adjust a trajectory of the beam incident on the optical element; and
one or more computer subsystems connected to the charged particle beam column and configured to control the scanning deflector and the adjustment deflector, wherein
the one or more computer subsystems include a user interface configured to display an image output from the charged particle beam column and a partial region of the image selected by a user, and
based on relationship information including a scanning speed of the scanning deflector and a change speed of the optical element, the one or more computer subsystems control at least one of the scanning deflector or the optical element such that a change time of one period of the optical element at the partial region is longer than a time per frame.

21. The charged particle beam system according to claim 20, wherein
the one or more computer subsystems
display, on the user interface, an input portion for allowing a user to set at least one of the image, the partial region of the image, a first parameter relating to the scanning speed of the scanning deflector, or a second parameter relating to the change speed of the optical element, and
based on one of the set first parameter or the set second parameter and the relationship information, determine the other of the first parameter or the second parameter.
